(19) United States
(12) Patent Application Publication
(10) Pub. No.: US 2025/0365874 A1
(43) Pub. Date: Nov. 27, 2025

(54) ELECTRONIC DEVICE FOR CURBSTONE

(71) Applicant: Che-An Liu, Taichung City (TW)

(72) Inventor: Che-An Liu, Taichung City (TW)

(21) Appl. No.: 18/817,520

(22) Filed: Aug. 28, 2024

(30) Foreign Application Priority Data
May 23, 2024 (TW) 113119177

(51) Int. Cl. H05K 5/02; E01C 11/22; G03B 30/00; H05K 5/03; H05K 5/06

(52) U.S. Cl. CPC H05K 5/0217; E01C 11/222; H05K 5/03; H05K 5/061; G03B 30/00

(57) ABSTRACT

An electronic device is adapted for mounting to a curbstone. The curbstone has a top curbstone surface, a front curbstone surface, and a mounting space. The electronic device includes a housing, an electronic unit, and a top cover. The housing is mounted in the mounting space and defines a receiving space. The electronic unit is disposed in the receiving space. The top cover is connected to the housing and has an upper surface. The top cover is rotatable relative to the housing about an axis that is adjacent to a front side of the housing so that at least a portion of the upper surface is adapted to be flush with the top curbstone surface.

### CROSS-REFERENCE TO RELATED APPLICATION

This application claims priority to Taiwanese Invention patent application No. 113119177, filed on May 23, 2024, the entire disclosure of which is incorporated by reference herein.

### FIELD

The disclosure relates to an electronic device, and more particularly to an electronic device adapted for mounting to a curbstone.

### BACKGROUND

An image-capturing device, as disclosed in Taiwanese Invention Patent No. TWI838148B, is adapted to be mounted to a curbstone. The image-capturing device includes an electric control box unit that accommodates an image-capturing module. The electric control box unit has an upper cover to be flush with a top surface of the curbstone.

Before the image-capturing device is mounted to the curbstone, a mounting space is first cut in the curbstone by a cutting tool. Afterwards, the image-capturing device is mounted to the mounting space. In order to discharge water or to make the top surface of the curbstone conform to the terrain, the top surface of the curbstone may be oblique. As a result, the upper cover of the electric control box unit is unlikely to be flush with the top surface of the curbstone. A step difference is formed between the upper cover of the electric control box unit and the top surface of the curbstone, which may cause people to fall over or get injured. Further, due to the step difference, the electronic device may be damaged by a hit. In addition, an appearance of the electronic device after the electronic device is mounted to the curbstone is unaesthetic.

### SUMMARY

Therefore, an object of the disclosure is to provide an electronic device that can alleviate at least one of the drawbacks of the prior art.

According to the disclosure, an electronic device is adapted for mounting to a curbstone. The curbstone has a top curbstone surface that has front and rear ends opposite to each other in a front-rear direction, a front curbstone surface that is connected to the front end of the top curbstone surface, and a mounting space that is formed at an intersection of the top curbstone surface and the front curbstone surface. The electronic device includes a housing, an electronic unit, and a top cover.

The housing is adapted to be mounted in the mounting space and defines a receiving space.

The electronic unit is disposed in the receiving space.

The top cover is connected to the housing, is adjacent to top of the receiving space, and has an upper surface.

The top cover is rotatable relative to the housing about an axis that is adjacent to a front side of the housing so that the upper surface is adapted to be at least partially flush with the top curbstone surface.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a perspective view illustrating an electronic device according to an embodiment of the disclosure adapted to be mounted to a curbstone.

FIG. 2 is an exploded perspective view illustrating the electronic device and the curbstone.

FIG. 3 is a fragmentary perspective view of the embodiment illustrating a housing and a positioning member of the electronic device.

FIG. 4 is a fragmentary perspective view of the embodiment illustrating the housing.

FIG. 5 is a fragmentary sectional view of the embodiment illustrating a top cover of the electronic device to be flush with a top curbstone surface of a curbstone at a first position, where the top curbstone surface is horizontal.

FIG. 6 is a fragmentary sectional view taken along line VI-VI of FIG. 5.

FIG. 7 is a fragmentary sectional view of the embodiment illustrating the top cover to be flush with the top curbstone surface of the curbstone at a second position, where the top curbstone surface is inclined.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

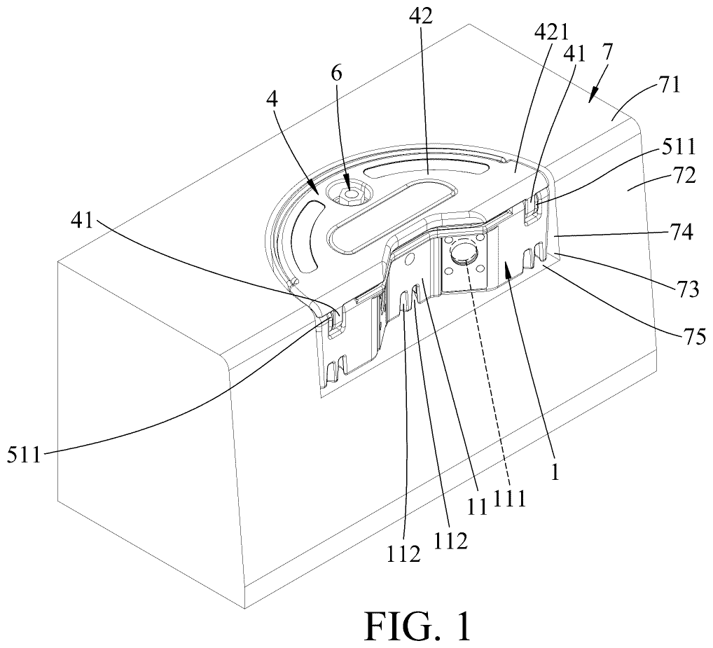

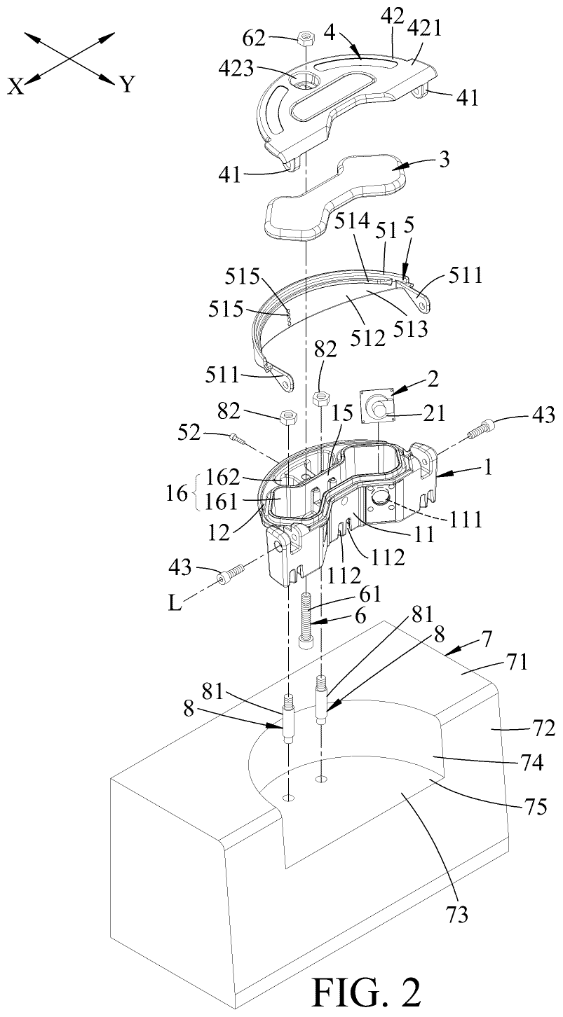

FIGS. 1 and 2 illustrate an electronic device according to an embodiment of the disclosure. The electronic device is adapted for mounting to a curbstone 7 by two mounting units 8.

The curbstone 7 is a border object disposed at a road edge to differentiate roadways, sidewalks, green grounds, or other road portions. The curbstone 7 may be made of concrete or stone. In this embodiment, the curbstone 7 has a top curbstone surface 71, a front curbstone surface 72, and a mounting space 73. The top curbstone surface 71 is elongated in a left-right direction (X) and has front and rear ends opposite to each other in a front-rear direction (Y) perpendicular to the left-right direction (X). The front curbstone surface 72 is connected to the front end of the top curbstone surface 71. The mounting space 73 is formed at an intersection of the top curbstone surface 71 and the front curbstone surface 72. As shown in FIG. 2, the curbstone 7 further has a curved neck portion 74 that extends downwardly from the top curbstone surface 71 and that has two opposite ends opposite to each other in the left-right direction (X) and connected to the front curbstone surface 72, and a mounting end portion 75 that is connected to bottom of the curved neck portion 74. The curved neck portion 74 and the mounting end portion 75 cooperatively define the mounting space 73.

Each of the mounting units 8 has a fastener 81 and a fixing nut 82. The fastener 81 is an expansion bolt that protrudes from the mounting end portion 75 into the mounting space 73.

The electronic device of the disclosure includes a housing 1, an electronic unit 2, a water-proof cover 3, a top cover 4, a positioning unit 5, and a fastening unit 6.

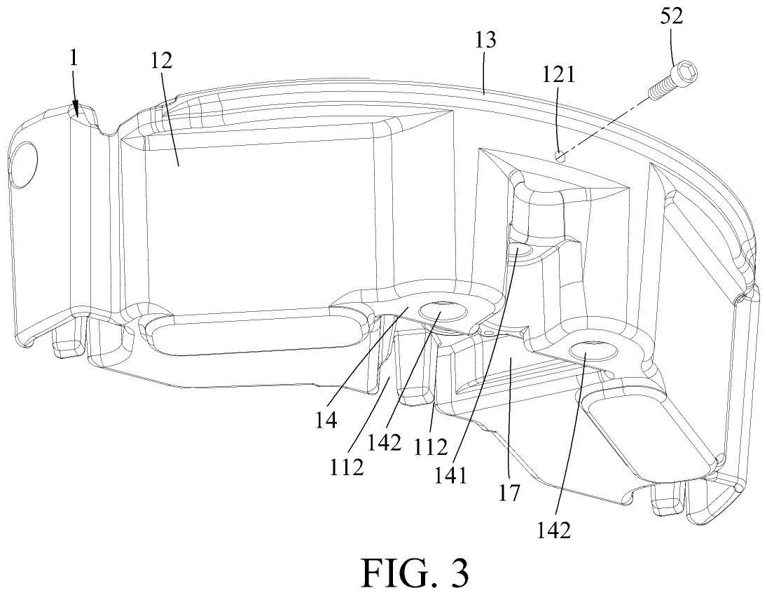

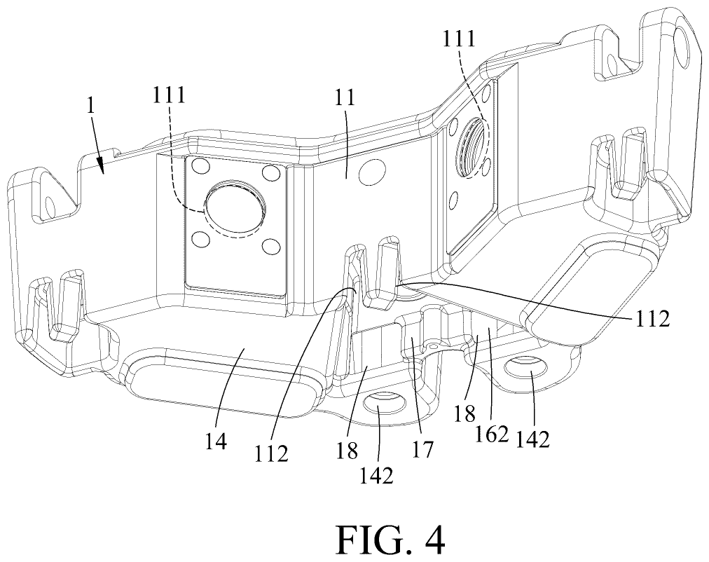

Referring to FIGS. 3 and 4 in combination with FIG. 2, the housing 1 is adapted to be mounted in the mounting space 73, and has a front wall 11, a support wall 12, an outer protrusion 13, a bottom wall 14, and a partition wall 15. The support wall 12 is connected to the front wall 11. The support wall 12 and the front wall 11 cooperatively define a receiving space 16. The outer protrusion 13 protrudes from the support wall 12 and is away from the receiving space 16. The bottom wall 14 is connected to the front wall 11 and the support wall 12. The partition wall 15 is disposed in the receiving space 16.

The front wall 11 is concave relative to the receiving space 16, and is formed with two windows 111 communicating with the receiving space 16. The windows 111 are spaced apart from each other in the left-right direction (X) and are oblique relative to each other. The housing 1 further has two front drainage holes 112 formed in the front wall 11. The front drainage holes 112 extend upwardly from a bottom side of the front wall 11 and are disposed between the windows 111. The number of the windows 111 is not limited hereto. In some embodiments, the number of the windows 111 may be only one.

A top end of the support wall 12 has a contour in a curved form. The support wall 12 has an adjustment threaded hole 121 extending therethrough. The adjustment threaded hole 121 is disposed below the outer protrusion 13 and is in communication with the receiving space 16.

The housing 1 further has a fixing hole 141 and two mounting holes 142. The fixing hole 141 and the two mounting holes 142 are formed in the bottom wall 14. The two mounting holes 142 are disposed below the outer protrusion 13. The fixing hole 141 is disposed between the outer protrusion 13 and the two mounting holes 142.

The partition wall 15 divides the receiving space 16 into a first receiving chamber 161 and a second receiving chamber 162 in the front-rear direction (Y). The first receiving chamber 161 is located between the partition wall 15 and the front wall 11, and is in communication with the windows 111. The second receiving chamber 162 is located between the partition wall 15 and the support wall 12. The fixing hole 141 and the mounting holes 142 are in communication with the second receiving chamber 162. The mounting holes 142 are respectively adapted to allow the fasteners 81 to extend therethrough for fixing the housing 1 to the curbstone 7.

The housing 1 further defines a drainage space 17 that is opposite to the receiving space 16, that is limited by the bottom wall 14, and that is in fluid communication with the front drainage holes 112. The housing 1 further has two rear drainage holes 18 that are located on a side of the drainage space 17 opposite to the front drainage holes 112 in the front-rear direction (Y), that are respectively adjacent to the mounting holes 142, and that are in fluid communication with the second receiving chamber 162 and the drainage space 17. The front drainage holes 112 and the rear drainage holes 18 function to discharge water from the second receiving chamber 162. The number of the front drainage holes 112 and the number of the rear drainage holes 18 are not limited hereto. In some embodiments, the number of the front drainage holes 112 and the number of the rear drainage holes 18 may be one or more than three.

The electronic unit 2 is mounted in the first receiving chamber 161, and includes an electronic gadget 21 that is disposed in the first receiving chamber 161 and that faces one of the windows 111. In this embodiment, the electronic gadget 21 is an image-capturing gadget to record a license plate of a vehicle parked beside the curbstone 7, so a parking fee of the vehicle can be computed by the electronic device of the disclosure. In other embodiments, the electronic gadget 21 may function as a projector for advertisement. The electronic gadget 21 is not limited hereto. The electronic gadget 21 may be disposed in a region of the first receiving chamber 161 adjacent to the other one of the windows 111 so as to face the other one of the windows 111. Alternatively, the electronic unit 2 may include two electronic gadgets 21 that respectively face the windows 11.

The water-proof cover 3 removably covers the first receiving chamber 161 and is a rubber pad.

As shown in FIGS. 1, 2, and 5, the top cover 4 is connected to the housing 1, and is adjacent to top of the receiving space 16. In this embodiment, the top cover 4 is rotatable about an axis (L) adjacent to a front side of the housing 1 relative to the housing 1. The axis (L) extends in the left-right direction (X) and is adjacent to top of the front wall 11 of the housing 1. The top cover 4 includes two rotary portions 41 and a top cover body 42.

The two rotary portions 41 are pivotally connected to the front wall 11 of the housing 1. Each of the rotary portions 41 is pivotally connected to the front wall 11 by a pivot screw 43. The axis (L) extends through the rotary portions 41.

The top cover body 42 is connected to the rotary portions 41, and has an upper surface 421, a lower surface 422, a recess 423, and a through hole 424. The lower surface 422 is opposite to the upper surface 421. The recess 423 is indented from the upper surface 421. The through hole 424 extends from the lower surface 422 to the recess 423 and is adjacent to the second receiving chamber 162.

The positioning unit 5 is connected to the housing 1, and includes an outer frame 51 and a positioning member 52.

The outer frame 51 is rotatably connected to the housing 1, and has two pivotal portions 511 and a frame portion 512. The two pivotal portions 511 are pivotally connected to the front wall 11 of the housing 1. The frame portion 512 interconnects the pivotal portions 511, and is disposed outside of the receiving space 16.

The axis (L) extends through the pivotal portions 511. The pivotal portions 511 are respectively adjacent to the rotary portions 41 of the top cover 4. Each of the pivotal portions 511 and the respective one of the rotary portions 41 are pivotally connected to the front wall 11 by the pivot screw 43.

The frame portion 512 of the outer frame 51 is shaped in a curved strap and surrounds a top portion of the support wall 12. The frame portion 512 has an inner surface 513 that faces the support wall 12 of the housing 1, and an inner protrusion 514 that is in a curved form and that protrudes from the inner surface 513. The inner protrusion 514 has two opposite ends respectively adjacent to the pivotal portions 511. The top cover body 42 abuts against top of the inner protrusion 514. The frame portion 512 of the outer frame 51 further has a plurality of positioning holes 515. The positioning holes 515 are disposed below the inner protrusion 514, are arranged in a line, and extend through the inner surface 513.

The positioning member 52 is detachably connected to the outer frame 51 and the support wall 12 of the housing 1 for positioning the outer frame 51 relative to the housing 1. In this embodiment, the positioning member 52 detachably extends through one of the positioning holes 515 for positioning the frame portion 512 of the outer frame 51 relative to the support wall 12 of the housing 1. Specifically, the positioning member 52 is a screw that is threadedly fastened into the adjustment threaded hole 121 of the support wall 12 so as to position the frame portion 512 to the support wall 12.

The fastening unit 6 is disposed on the housing 1, and includes a bolt 61 and a nut 62. The bolt 61 is threadedly fastened to the fixing hole 141 of the housing 1 and extends upwardly through the second receiving chamber 162 and the through hole 424 into the recess 423. The nut 62 is disposed in the recess 423 and is threadedly connected to a top end of the bolt 61.

In practice, the top curbstone surface 71 of the curbstone 7 may be oblique in order to facilitate water discharge. After the housing 1 is mounted in the mounting space 73 of the curbstone 7, rotating the top cover 4 relative to the housing 1 may adjust the top cover 4 to be flush with the top curbstone surface 71. Adjusting the top cover 4 to be flush with the top curbstone surface 71 will be described hereinafter.

The positioning member 52 and the nut 62 are first removed. When the positioning member 52 is detached from the outer frame 51 and the housing 1, the outer frame 51 and the top cover 4 are simultaneously rotatable relative to the housing 1 to move the top cover 4 between a first position, where the inner protrusion 514 of the frame portion 512 abuts against a top of the outer protrusion 13, and a second position, where the inner protrusion 514 of the frame portion 512 is disposed above and away from the outer protrusion 13. As long as the top cover 4 is ensured to be flush with the top curbstone surface 71, the positioning member 52 extends through a corresponding one of the positioning holes 515 and is threadedly fastened to the adjustment threaded hole 121 of the support wall 12, thereby positioning the outer frame 51 fixedly to the housing 1. Because the top cover 4 abuts against the inner protrusion 514 of the outer frame 51, the top cover 4 is fixed at an angle relative to the housing 1. By virtue of fastening the nut 62 to the top end of the bolt 61 within the recess 423, the top cover 4 is prevented from being opened.

When the electronic unit 2 needs to be checked or repaired, the nut 62 is removed so that the top cover 4 can be opened and the water-proof cover 3 can be removed for checking or repairing the electronic unit 2. In this embodiment, the nut 62 is a hexagon nut. In other embodiments, the nut 62 may be an anti-theft nut to prevent the top cover 4 from being opened and the electronic unit 2 from being damaged.

In this embodiment, the top cover 4 is adjustable to be rotated in an angular range of about 8 degrees, but it is not limited hereto. In variant embodiments, after the housing 1 and the outer frame 51 are modified in shape and structure, the top cover 4 may be adjustable to be rotated in an angular range of about 30 degrees.

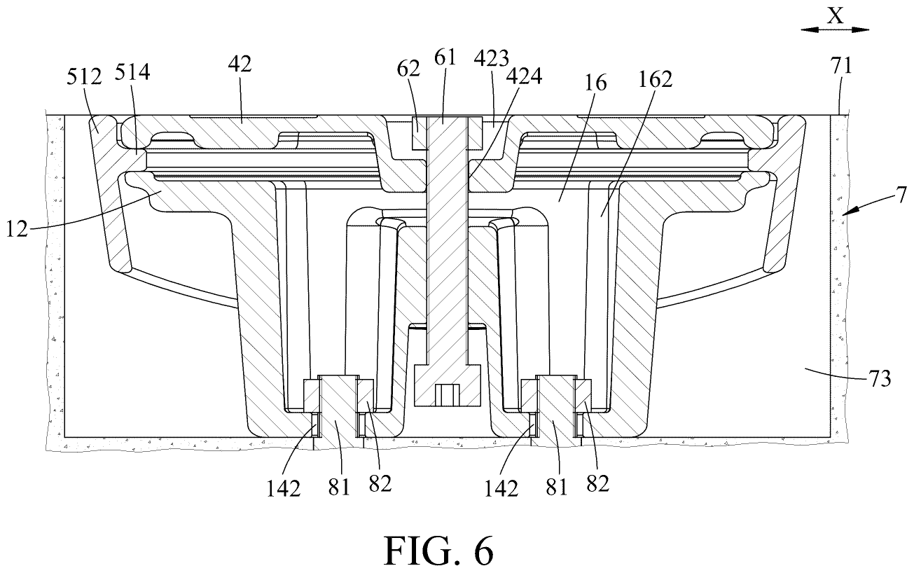

As shown in FIGS. 2, 5, and 6, the top curbstone surface 71 is substantially horizontal. Mounting the electronic device of the disclosure to the curbstone 7 will be described as follows.

First, the positioning member 52 and the nut 62 are removed, and the electronic device is placed into the mounting space 73. The outer frame 51 and the top cover 4 are simultaneously adjusted to rotate in order to ensure that the upper surface 421 of the top cover body 42 is flush with the top curbstone surface 71. Afterwards, the electronic device of the disclosure is taken out from the mounting space 73. The positioning member 52 extends through a corresponding one of the positioning holes 515 and is threadedly fastened to the adjustment threaded hole 121 of the support wall 12, thereby positioning the outer frame 51 fixedly to the housing 1. Subsequently, the fasteners 81 of the mounting units 8 are anchored to the mounting end portion 75 of the curbstone 7. The electronic device of the disclosure is placed into the mounting space 73 in a manner where the fasteners 81 extend respectively through the mounting holes 142. The fixing nuts 82 are respectively fastened to the fasteners 81, thereby fixing the electronic device of the disclosure to the curbstone 7. After the nut 62 is fastened to the top end of the bolt 61, the top cover 4 is prevented from being opened.

In other embodiments, the number of the fasteners 81 and the number of the mounting holes 142 are not limited hereto, and may be one or more than three.

Noticeably, when the top curbstone surface 71 is substantially horizontal, and when the upper surface 421 of the top cover body 42 is flush with the top curbstone surface 71, the top cover 4 is located at the first position, and the positioning member 52 extends through the topmost one of the positioning holes 515. The inner protrusion 514 of the frame portion 512 abuts against the top of the outer protrusion 13 to prevent the outer frame 51 from rotating downwardly relative to the housing 1, thereby ensuring that the upper surface 421 of the top cover body 42 is horizontal and is flush with the top curbstone surface 71.

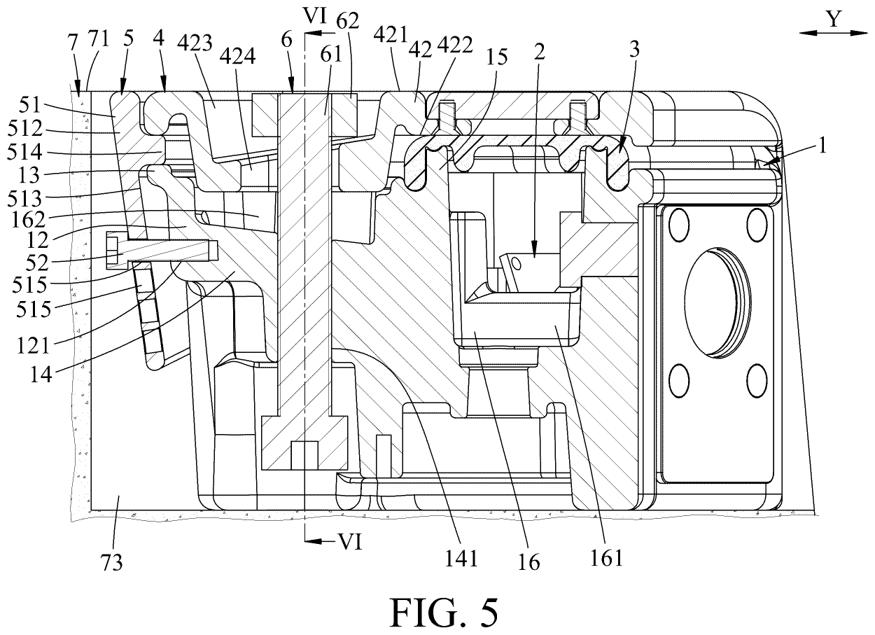

Referring back to FIGS. 4 and 5, when liquid flows into the housing 1 through a gap formed between the frame portion 512 of the outer frame 51 and the top cover body 42, the water-proof cover 3 prevents the liquid from entering the first receiving chamber 161, thereby protecting the electronic gadget 21 disposed in the first receiving chamber 161. Meanwhile, the liquid may be discharged from the second receiving chamber 162, the rear drainage holes 18, the drainage space 17, and the front drainage holes 112, thereby achieving a satisfactory drainage effect.

In this embodiment, the electronic unit 2 is wirelessly connected to a server (not shown) for transmission of image information. In other embodiments, a signal wire (not shown) coupled to the server may be buried in the curbstone 7 and extend to the mounting space 73. As a result, the electronic unit 2 may transmit information to the server through the signal wire.

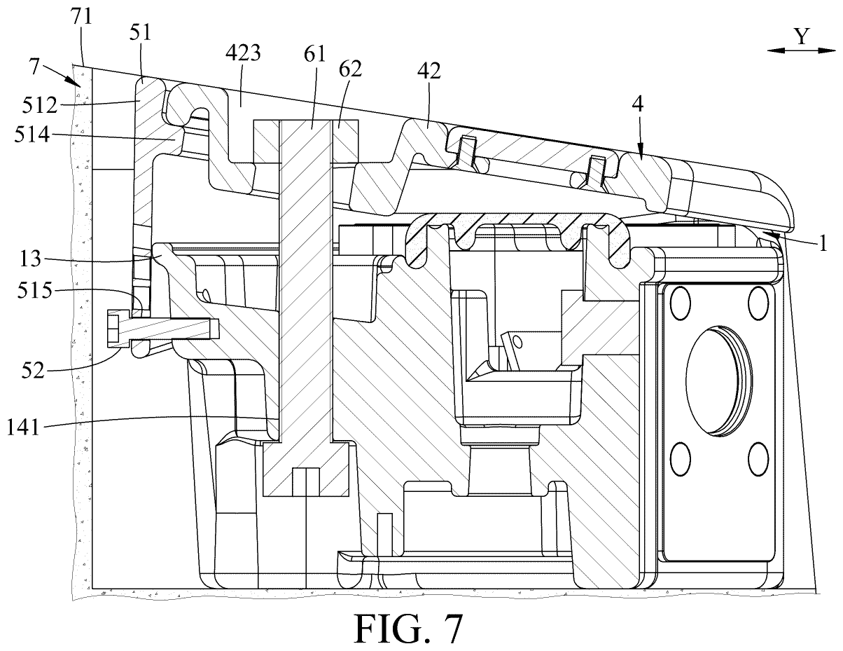

Referring to FIG. 7, when the top curbstone surface 71 of the curbstone 7 is oblique forwardly and downwardly in the front-rear direction (Y), by detaching the positioning member 52 from the outer frame 51 and the housing 1, the outer frame 51 and the top cover 4 are simultaneously adjusted in rotation relative to the housing 1 to move the top cover 4 to the second position. The top cover body 42 is oblique forwardly and downwardly in the front-rear direction (Y), such that the upper surface 421 is flush with the top curbstone surface 71. Meanwhile, the inner protrusion 514 of the frame portion 512 is disposed above and away from the outer protrusion 13. The positioning member 52 extends through the lowest one of the positioning holes 515. By driving the bolt 61 to move upwardly, the top end of the bolt 61 extends into the recess 423 such that the nut 62 is threadedly connected to the top end of the bolt 61. In practice, though the top curbstone surfaces of the curbstones are oblique by different angles, because the top cover 4 is adjustable to be rotated to thereby be able to be flush with the top curbstone surfaces of the curbstones that are oblique by different angles, the electronic device of the disclosure is suitable to be mounted to a curbstone that is different from the curbstone 7 in the disclosure.

In summary, by virtue of the top cover 4 being rotatable relative to the housing 1, when the housing 1 is mounted in the mounting space 73, at least a portion of the upper surface 421 of the top cover 4 is flush with the top curbstone surface 71. Not only is an appearance of the electronic device aesthetic, but the electronic device is also prevented from being damaged by a hit.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. An electronic device adapted for mounting to a curbstone, the curbstone having a top curbstone surface that has front and rear ends opposite to each other in a front-rear direction, a front curbstone surface that is connected to the front end of the top curbstone surface, and a mounting space that is formed at an intersection of the top curbstone surface and the front curbstone surface, said electronic device comprising:
a housing that is adapted to be mounted in the mounting space and that defines a receiving space;
an electronic unit that is disposed in said receiving space; and
a top cover that is connected to said housing, that is adjacent to top of said receiving space, and that has an upper surface;
wherein said top cover is rotatable relative to said housing about an axis that is adjacent to a front side of said housing so that at least a portion of said upper surface is adapted to be flush with the top curbstone surface.

2. The electronic device as claimed in claim 1, wherein said axis extends in a left-right direction perpendicular to the front-rear direction and is adjacent to top of said front side of said housing.

3. The electronic device as claimed in claim 1, wherein:
said top cover includes
two rotary portions that are pivotally connected to said housing, and
a top cover body that is connected to said rotary portions and that has said upper surface;
said axis extends through said rotary portions;
said electronic device further comprises a positioning unit that is connected to said housing;
said positioning unit includes an outer frame that is rotatably connected to said housing, and a positioning member that is detachably connected to said outer frame and said housing for positioning said outer frame relative to said housing;
said outer frame has
two pivotal portions that are pivotally connected to said housing, and
a frame portion that interconnects said pivotal portions, that is disposed outside of said receiving space, and that has an inner surface facing said housing, and an inner protrusion protruding from said inner surface; and
said top cover body abuts against top of said inner protrusion.

4. The electronic device as claimed in claim 3, wherein said axis extends through said pivotal portions of said outer frame.

5. The electronic device as claimed in claim 3, wherein:
said frame portion of said outer frame further has a plurality of positioning holes extending through said inner surface; and
said positioning member detachably extends through one of said positioning holes for positioning said frame portion relative to said housing.

6. The electronic device as claimed in claim 3, wherein:
said housing has
a front wall,
a support wall that is connected to said front wall, said support wall and said front wall cooperatively defining said receiving space, and
an outer protrusion that protrudes from said support wall and that is away from said receiving space; and
when said positioning member is detached from said outer frame and said housing, said outer frame and said top cover are simultaneously rotatable relative to said housing to move said top cover between a first position, where said inner protrusion of said frame portion abuts against top of said outer protrusion, and a second position, where said inner protrusion of said frame portion is disposed above and away from said outer protrusion.

7. The electronic device as claimed in claim 1, wherein:
said housing has a partition wall that divides said receiving space into a first receiving chamber and a second receiving chamber;
said electronic device further comprises a water-proof cover that removably covers said first receiving chamber; and
said electronic unit is mounted in said first receiving chamber.

8. The electronic device as claimed in claim 7, wherein:
said housing has at least one mounting hole that is formed in a bottom portion of said housing and that communicates with said second receiving chamber, said at least one mounting hole being adapted to allow at least one fastener to extend therethrough for fixing said housing to the curbstone;
said housing further has at least one front drainage hole formed in said front side thereof;
said housing further defines a drainage space that is opposite to said receiving space, that is limited by said bottom portion of said housing, and that is in fluid communication with said at least one front drainage hole;
said housing further has at least one rear drainage hole that is located on a side of said drainage space opposite to said at least one front drainage hole in the front-rear direction, that is adjacent to said at least one mounting hole, and that is in fluid communication with said second receiving chamber and said drainage space.

9. The electronic device as claimed in claim 1, wherein:
said top cover further has
a lower surface that is opposite to said upper surface,
a recess that is indented from said upper surface, and
a through hole that extends from said lower surface to said recess;
said electronic device further comprises a fastening unit that is disposed on said housing; and
said fastening unit includes
a bolt that extends upwardly through said through hole into said recess, and
a nut that is disposed in said recess and that is threadedly connected to a top end of said bolt.

10. The electronic device as claimed in claim 1, wherein:
said front side of said housing is formed with at least one window communicating with said receiving space; and
said electronic unit includes an electronic gadget disposed in said receiving space and facing said at least one window.
